(19) United States
(12) Patent Application Publication
(10) Pub. No.: US 2021/0389059 A1
(43) Pub. Date: Dec. 16, 2021

(54) RIVETING APPARATUS FOR THIN HEAT SINK FIN AND THIN COVER PLATE

(71) Applicant: Dong Guan Han Xu Hardware & Plastic Technology Co., Ltd., Dongguan City (CN)

(72) Inventor: Tsung-Hsien Huang, Dongguan City (CN)

(21) Appl. No.: 17/460,328

(22) Filed: Aug. 30, 2021

Related U.S. Application Data
(63) Continuation-in-part of application No. 16/698,952, filed on Nov. 28, 2019.

(30) Foreign Application Priority Data
Dec. 28, 2018 (CN) 201811622595.9

(51) Int. Cl. F28F 3/06; B21D 39/03

(52) U.S. Cl. CPC F28F 3/06; B21D 39/031

(57) ABSTRACT

A riveting structure for a thin heat sink fin and a thin cover plate is disclosed. The riveting structure includes a plurality of thin heat sink fins and a thin cover plate. The top of each thin heat sink fin is provided with a raised portion, the thin cover plate is formed with a plurality of cover plate riveting holes, and the raised portion is pressed and deformed by a rolling device in a rolling manner to fill the space of a corresponding one of the cover plate riveting holes, thereby fixing the raised portion. It is suitable for a “thin” design, improves the assembly efficiency greatly, reduces the labor cost, and reduces the product defect rate effectively.

### CROSS REFERENCE TO RELAYED APPLICATIONS

This is a continuation-in-part application of co-pending U.S. patent application Ser. No. 16/698,952, “RIVETING APPARATUS FOR THIN HEAT SINK FIN AND THIN COVER PLATE”, filed on Nov. 28, 2019.

### BACKGROUND OF THE INVENTION

### 1. Field of the Invention

The present invention relates to an apparatus for manufacturing a heat sink, and more particularly to a riveting structure for a thin heat sink fin and a thin cover plate.

### 2. Description of the Prior Art

A heat sink usually includes a heat sink base and heat sink fins disposed on the heat sink base. In order to improve the heat dissipation effect, a conventional heat sink generally adopts thin heat sink fins. Since a single thin heat sink fin is weak and easily deformed, a thin cover plate is mounted on the plurality of thin heat sink fins to enhance the overall strength of the heat sink. In the prior art, the thin cover plate is assembled to the heat sink fins by manual welding. This assembly is inefficient and labor intensive, and the thin cover plate is easily damaged by welding, resulting in defective products.

There are various mold bending and riveting methods on the market. For example, Chinese Utility Model Publication No. CN206779311U discloses a roller-type high-efficiency riveting mold. It relates to a workpiece fixing jig for positioning pins of fins and pin holes of a perforated plate. As the workpiece fixing jig moves horizontally along a horizontal guide rail, the pins of fins will bend in the same direction under the pressure of a roller to achieve riveting with the perforated plate. The pins of the fins are bent and riveted with the pins holes of the perforated plate, that is, the pins are bent and hasped on the surface of the perforated plate by riveting. In this way, there will be more technical defects. On the one hand, because the pins are hasped on the surface of the perforated plate after the pins are bent, the fit between the pins and the pin holes is often loose. The pins hasped on the perforated plate will increase the overall thickness of the product (that is, the upper surface of the perforated plate increases the thickness of each pin), which is not suitable for a “thin” design. The bent pins each have a barb shape, which is very inconvenient for installation. On the other hand, the pin bends under the pressure of the roller. In the process of rolling and bending, the pressure of the roller is transmitted to the perforated plate through the pins. For a good fixing effect of the bent and riveted pins (that is, to avoid loosening), it is necessary to ensure that the bent pins fit tightly with the upper surface of the perforated plate as much as possible, otherwise the connection of the bent pins and the pin holes will easily loosen. In this way, the pressure of the roller must be sufficient. At this time, the perforated plate is equivalent to directly bear the pressure of the roller, and the upper surface of the perforated plate is easily deformed after being pressed, and the fins may be broken. Therefore, it is required to increase the thickness of the perforated plate to prevent deformation, which obviously does not conform to the current development trend of light, thin, short, and small products.

Accordingly, the inventor of the present invention has devoted himself based on his many years of practical experiences to solve these problems.

### SUMMARY OF THE INVENTION

In view of the shortcomings of the prior art, the primary object of the present invention is to provide a riveting structure for a thin heat sink fin and a thin cover plate, which can improve assembly efficiency and reduce product defects and make the overall product thin and flat.

In order to achieve the above object, the present invention adopts the following technical solutions:

A riveting structure for a thin heat sink fin and a thin cover plate is provided. The riveting structure comprises a plurality of thin heat sink fins and a thin cover plate. The plurality of thin heat sink fins are vertically disposed. The thin cover plate is disposed on top of the thin heat sink fins. Each of the thin heat sink fins has a raised portion extending from a top thereof The thin cover plate is formed with a plurality of cover plate riveting holes. The raised portion of each thin heat sink fin passes through a corresponding one of the cover plate riveting holes to extend upward. The raised portion of each thin heat sink fin is pressed and deformed to fill a space in the corresponding cover plate riveting hole by a rolling device in a rolling manner, so as to be riveted and fixed to the corresponding cover plate riveting hole. The deformed raised portion after being pressed is flush with a surface of the thin cover plate.

Preferably, the top of each thin heat sink fin is provided with a plurality of evenly spaced raised portions.

Preferably, the raised portion has a flat top surface.

Preferably, the raised portion has a toothed top surface.

Preferably, the raised portion has a curved concave top surface.

Preferably, the cover plate riveting holes each have a square shape.

Preferably, the volume of the raised portion is slightly greater than the volume of the cover plate riveting hole.

Compared with the prior art, the present invention has obvious advantages and beneficial effects. Specifically, it can be known from the above technical solutions:

In the present invention, the top of each thin heat sink fin is provided with the raised portion, the thin cover plate is formed with the plurality of cover plate riveting holes, and the raised portion is pressed and deformed by the rolling device in a rolling manner to fill a space in the corresponding cover plate riveting hole, so as to be riveted and fixed in the cover plate riveting hole. It is suitable for a “thin” design, and is beneficial to reduce the weight of the product, instead of the traditional manual welding method. The present invention improves the assembly efficiency greatly, reduces the labor cost, and reduces the product defect rate effectively. The overall product structure is stable, not easy to fall off and deform, and the product is thin and flat.

### BRIEF DESCRIPTION OF THE DRAWINGS

FIG. 1 is a perspective view in accordance with a preferred embodiment of the present invention;

FIG. 2 is an exploded view in accordance with the preferred embodiment of the present invention;

FIG. 3 is a partially assembled view in accordance with the preferred embodiment of the present invention;

FIG. 4 is a bottom perspective view of the rolling device in accordance with the preferred embodiment of the present invention;

FIG. 5 is an exploded view of the thin heat sink fins and the thin cover plate in accordance with the preferred embodiment of the present invention;

FIG. 6 is a perspective view of the thin heat sink fins and the thin cover plate in accordance with the preferred embodiment of the present invention;

FIG. 7 is an exploded view of a first example of the thin heat sink fin s and the thin cover plate in accordance with the preferred embodiment of the present invention;

FIG. 8 is a perspective view of the first example of the thin heat sink fins and the thin cover plate in accordance with the preferred embodiment of the present invention;

FIG. 9 is a perspective view of the first example of the thin heat sink fins and the thin cover plate after riveted in accordance with the preferred embodiment of the present invention;

FIG. 10 is an exploded view of a second example of the thin heat sink fins and the thin cover plate in accordance with the preferred embodiment of the present invention;

FIG. 11 is a perspective view of the second example of the thin heat sink fins and the thin cover plate in accordance with the preferred embodiment of the present invention;

FIG. 12 is a perspective view of the second example of the thin heat sink fins and the thin cover plate after riveted in accordance with the preferred embodiment of the present invention;

FIG. 13 is an exploded view of a third example of the thin heat sink fins and the thin cover plate in accordance with the preferred embodiment of the present invention;

FIG. 14 is a perspective view of the third example of the thin heat sink fins and the thin cover plate in accordance with the preferred embodiment of the present invention; and

FIG. 15 is a perspective view of the third example of the thin heat sink fins and the thin cover plate after riveted in accordance with the preferred embodiment of the present invention.

### DETAILED DESCRIPTION OF THE PREFERRED EMBODIMENTS

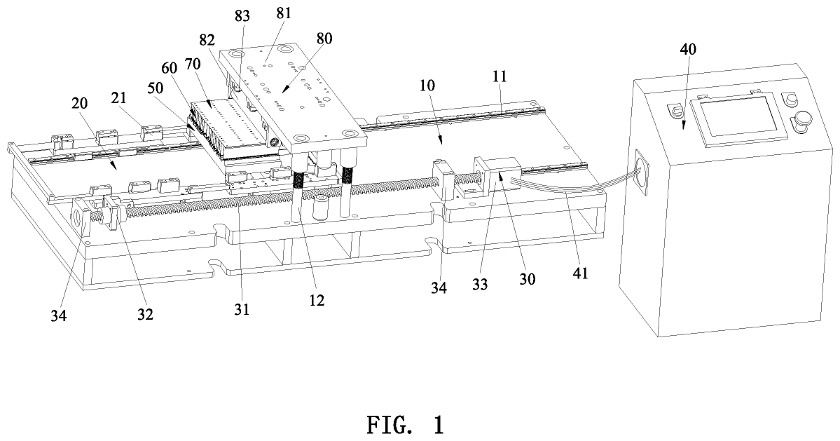

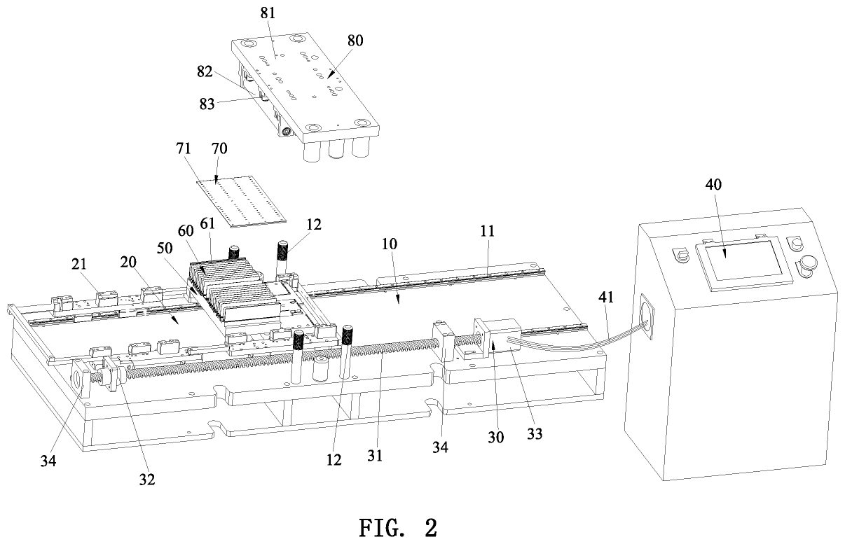

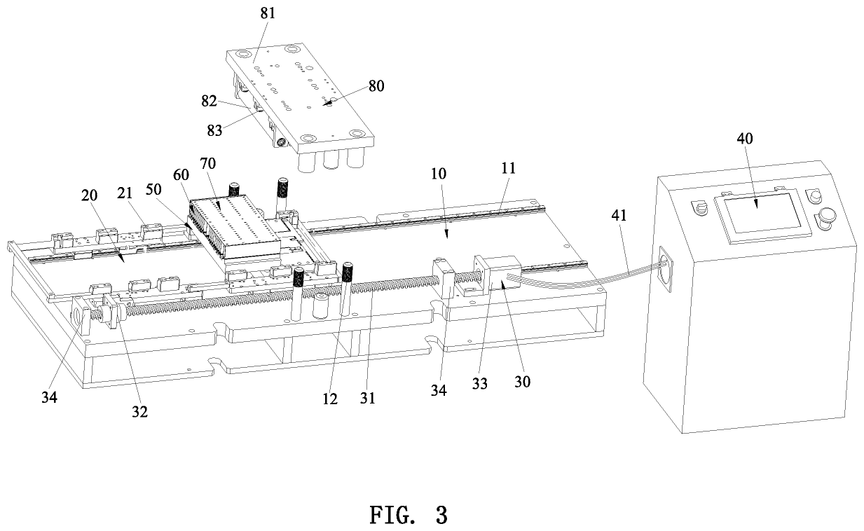

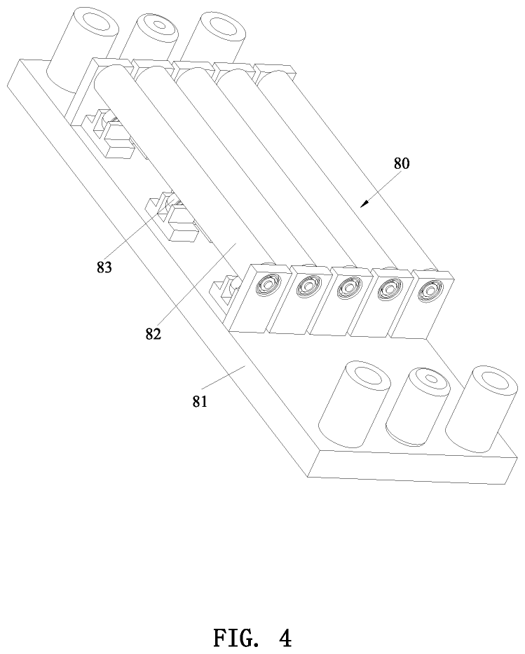

Referring to FIG. 1 through FIG. 4, a riveting apparatus for a thin heat sink fin and a thin cover plate according to a preferred embodiment of the present invention comprises a worktable 10, a feed frame 20, a driving device 30, and a control box 40.

The feed frame 20 is movably disposed on the worktable 10 to move back and forth transversely. The feed frame 20 is configured to carry a heat sink base 50. A plurality of thin heat sink fins 60 are vertically disposed on the heat sink base 50. The plurality of thin heat sink fins 60 are covered with a thin cover plate 70. The thin cover plate 70 is formed with a plurality of cover plate riveting holes 71. The top of each thin heat sink fin 60 is provided with a plurality of evenly spaced raised portions 61. The raised portion61 of each thin heat sink fin 60 passes through a corresponding one of the cover plate riveting holes 71 to extend upward. The cover plate riveting holes 71 each have a square shape. In this embodiment, a slide rail seat 11 having two rails arranged in parallel is disposed on the worktable 10. The feed frame 20 is moved back and forth transversely along the slide rail seat 11. The feed frame 20 is provided with a plurality of spaced retaining blocks 21 for supporting the heat sink base 50.

The driving device 30 is disposed on the worktable 10 for driving the feed frame 20 to move back and forth transversely. Specifically, the driving device 30 is fixedly disposed on one side of the worktable 10. The driving device 30 includes a screw rod 31, a driving block 32, and a motor 33. The screw rod 31 is driven and controlled by a motor 33. The driving block 32 is coupled to one side of the feed frame 20. When the motor 33 is actuated, the driving block 32 and the feed frame 20 are synchronously driven to move. Two ends of the screw rod 31 of the driving device 30 are provided with support blocks 34, respectively. The two ends of the screw rod 31 of the driving device 30 are inserted through the corresponding support blocks 34. The driving block 32 is threadedly sleeved onto the screw rod 31 and located between the two support blocks 34.

The control box 40 is connected to the driving device 30 and configured to control the driving device 30 to operate. A rolling device 80 is disposed at a riveting position of the worktable 10 for riveting the raised portions 61 in a rolling manner when the thin heat sink fins 60 and the thin cover plate 70 pass there. The control box 40 has a transmission cable 41connected to the motor 33 of the driving unit 30.

The rolling device 80 includes a baseplate 81 and a plurality of rollers 82. The baseplate 81 is fixed above the worktable 10. The plurality of rollers 82 are transversely arranged and rotationally mounted under the baseplate 81. Each roller 82 extends longitudinally. The raised portion 61 is pressed and deformed by the rolling device 80 in a rolling manner to fill the space in the cover plate riveting hole 71, so as to be riveted and fixed in the cover plate riveting hole 71. The deformed raised portion 61 is completely filled in the space of the cover plate riveting hole 71 and is flush with the surface of the thin cover plate 70. In this embodiment, the volume of the raised portion 61 is slightly greater than the volume of the cover plate riveting hole 71. Thus, the raised portion 61 is completely filled in the cover plate riveting hole 71 after being deformed, and the raised portion is more even with the surface of the thin cover plate after being pressed. The centers of rotation of the plurality of rollers 82 are located on the same horizontal plane. The outer diameters of the plurality of rollers 82 gradually increase in the conveying direction of the feed frame 20 for riveting the raised portions 61 stepwise in a rolling manner. This can prevent deformation of the thin heat sink fins 60 caused by one-time excessive rolling and riveting. The underside of the baseplate 81 is provided with a plurality of support rollers 83. The plurality of support rollers 83 abut against the corresponding rollers 82 to enhance the strength of the rollers 82 for riveting the raised portions 61 better in a rolling manner. Furthermore, two sides of the worktable 10 are provided with upright posts 12. The baseplate 18 is fixed to the tops of the upright posts 12.

The working principle of this embodiment is as follows:

In operation, the feed frame 20 is at the left side of the worktable 10. Firstly, the heat sink base 50 is retained on the feed frame 20, and the plurality of thin heat sink fins 60 are vertically disposed on the heat sink base 50 in advance. Next, the thin heat sink fins 60 are covered with the thin cover plate 70, and the raised portion 61 of each thin heat sink fin 60 passes through the corresponding cover plate riveting hole 71 to extend out. The control box 40 is preset with a work command Then, the driving device 30 begins to execute the work command, driving the feed frame 20 carrying the heat sink base 50, the thin heat sink fins 60 and the thin cover plate 70 to move right and pass through the rolling device 80. The respective rollers 82 of the rolling device 80 sequentially press the raised portion 61 of each thin heat sink fin 60, so that the raised portion 61 is deformed and riveted in the space of the corresponding cover plate riveting hole 71.The deformed raised portion 61 is completely filled in the space of the cover plate riveting hole 71 and is flush with the surface of the thin cover plate 70, so that the appearance of the product is flat and beautiful. The thin cover plate 70 and the thin heat sink fins 60 are fixed together to form a heat sink Finally, the heat sink is removed from the feed frame 20, and the driving device 30 is controlled by the control box 40 to operate, so that the driving device 30 drives the feed frame 20 to return reversely for the next riveting operation.

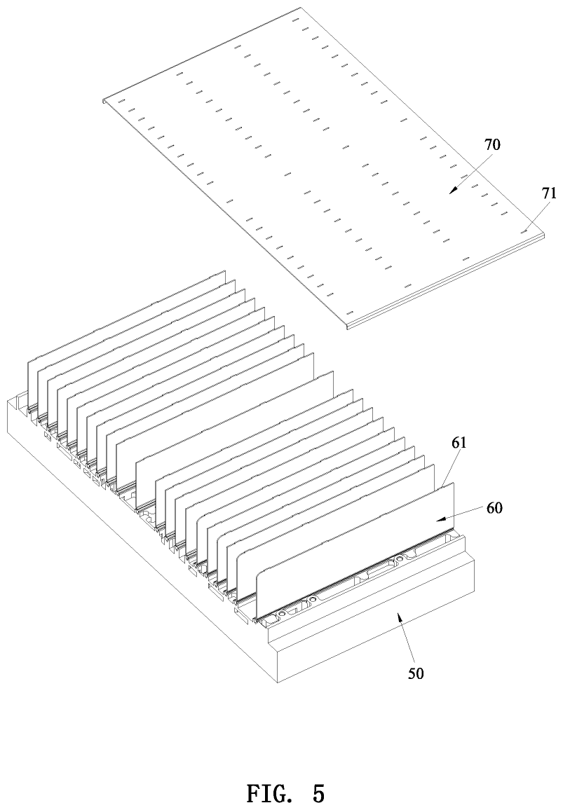

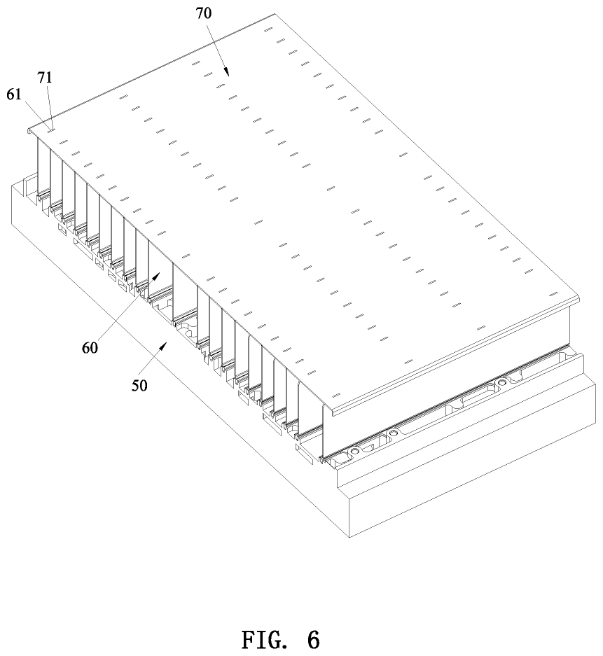

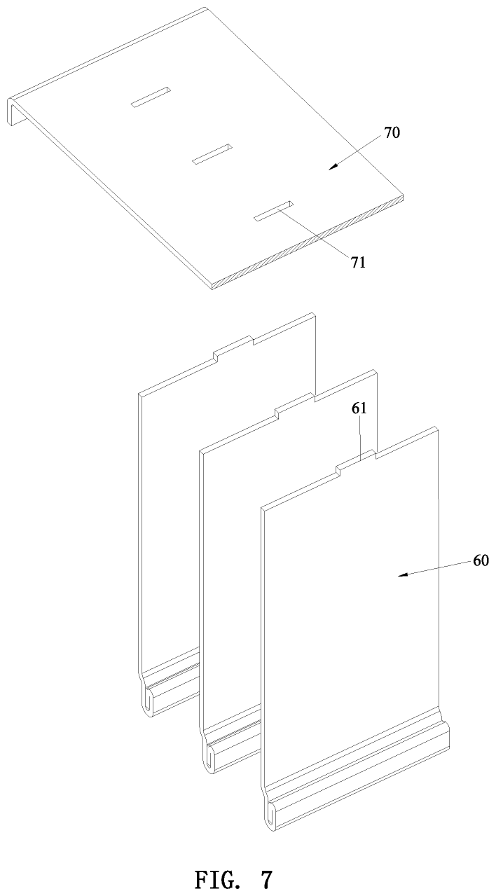

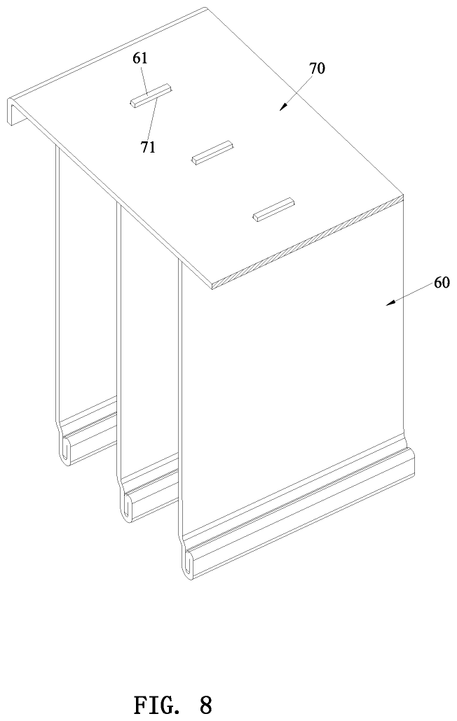

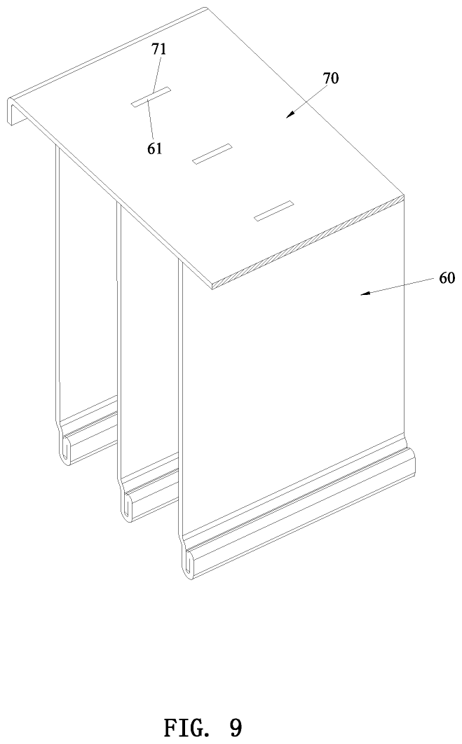

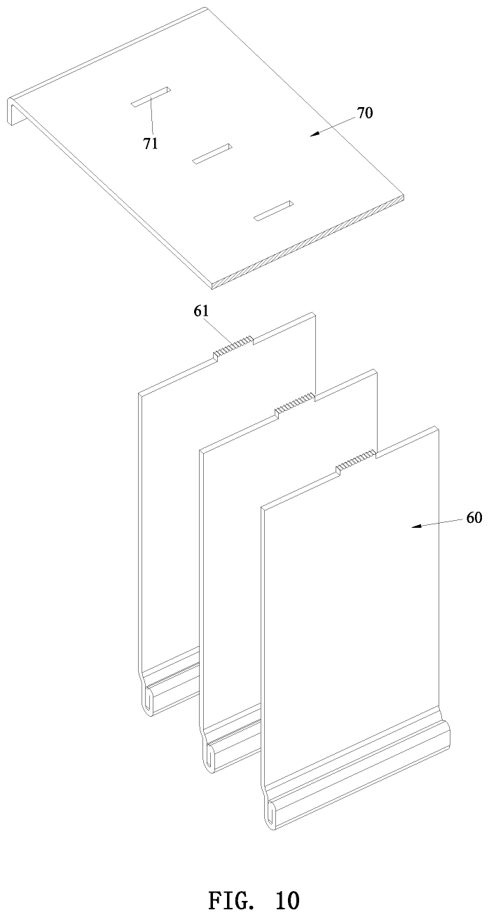

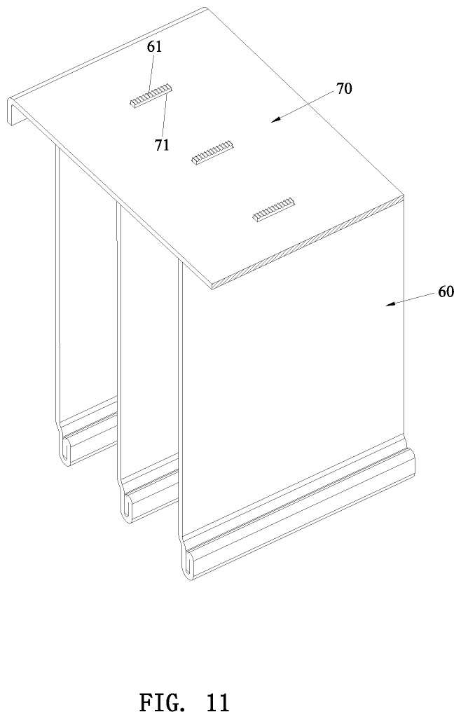

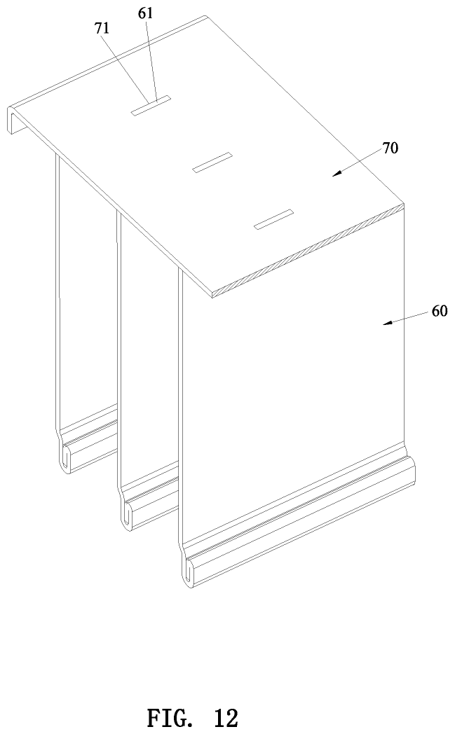

FIGS. 5-9 illustrate a first example of the thin heat sink fins 60 and the thin cover plate 70. Wherein, the top surface of the raised portion 61 is a flat surface. FIGS. 10-12 illustrate a second example of the thin heat sink fins and the thin cover plate. Wherein, the top surface of the raised portion 61 is a toothed surface. It is suitable for riveting thinner heat sink fins If the material is too thin, it bears less pressure, and it is prone to fracture. Therefore, in this embodiment, only the toothed portion is applied with a force to be deformed during rolling, so that the whole rolling stress is reduced, and the raised portion 61 can be better deformed to fill the space in the cover plate riveting hole 71.

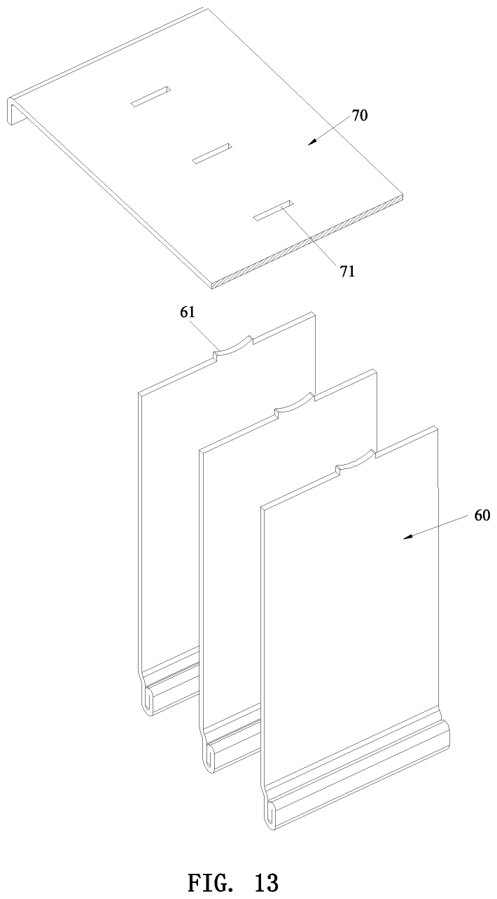

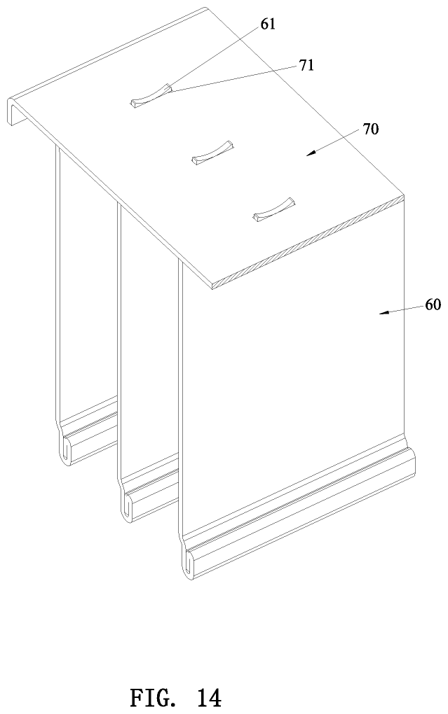

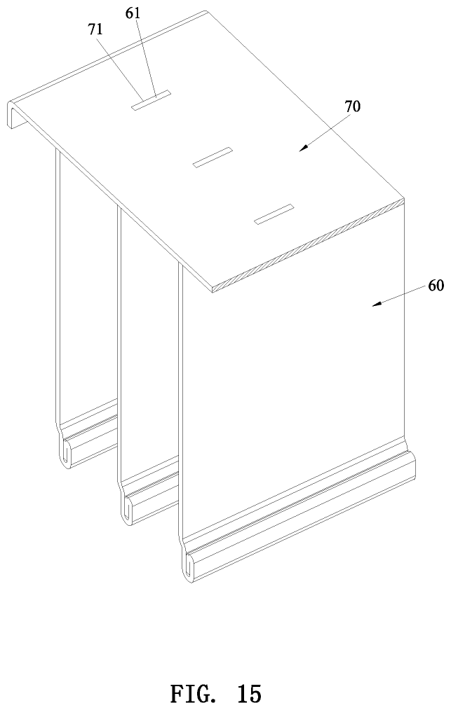

FIGS. 13-15 illustrate a third example of the thin heat sink fins and the thin cover plate. Wherein, the top surface of the raised portion 61 is a curved concave surface. When pressed in a rolling manner, only the curved raised portion needs to be pressed, and the purpose of reducing the rolling stress can be achieved, and the raised portion 61 can be better deformed to fill the space in the cover plate riveting hole 71.

The cover plate riveting hole 71 may be square, which can prevent the raised portion 61 of the thin heat sink fin 60 from rotating relative to the corresponding cover plate riveting hole 71 of the cover plate 70.

The volume of the raised portion 61 is slightly greater than the volume of the cover plate riveting hole 71. This ensures that the raised portion 61 can be fully filled in the space of the cover plate riveting hole 71 after being deformed by rolling, so that the surfaces of the thin heat sink fin 60 and the thin cover plate 70 can be riveted smoothly.

The feature of the present invention is that the top of each thin heat sink fin is provided with the raised portion, the thin cover plate is formed with the plurality of cover plate riveting holes, and the raised portion is pressed by the rolling device in a rolling manner for the raised portion to be deformed to fill the space in the corresponding cover plate riveting hole, so as to be riveted and fixed in the cover plate riveting hole. The deformed raised portion after being pressed is flush with the surface of the thin cover plate.

It is suitable for a “thin” design, and is beneficial to reduce the weight of the product, instead of the traditional manual welding method. The present invention improves the assembly efficiency greatly, reduces the labor cost, and reduces the product defect rate effectively. The overall product structure is stable, not easy to fall off and deform, and the product is thin and flat.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A riveting structure for a thin heat sink fin and a thin cover plate, comprising a plurality of thin heat sink fins and a thin cover plate; the plurality of thin heat sink fins being vertically disposed, the thin cover plate being disposed on top of the thin heat sink fins; each of the thin heat sink fins having a raised portion extending from a top thereof; the thin cover plate being formed with a plurality of cover plate riveting holes, the raised portion of each thin heat sink fin passing through a corresponding one of the cover plate riveting holes to extend upward, the raised portion of each thin heat sink fin being pressed and deformed by a rolling device in a rolling manner to fill a space in the corresponding cover plate riveting hole, so as to be riveted and fixed to the corresponding cover plate riveting hole, the raised portion after being pressed being flush with a surface of the thin cover plate.

2. The riveting structure as claimed in claim 1, wherein the top of each thin heat sink fin is provided with a plurality of evenly spaced raised portions.

3. The riveting structure as claimed in claim 1, wherein the raised portion has a flat top surface.

4. The riveting structure as claimed in claim 1, wherein the raised portion has a toothed top surface.

5. The riveting structure as claimed in claim 1, wherein the raised portion has a curved concave top surface.

6. The riveting structure as claimed in claim 1, wherein the cover plate riveting holes each have a square shape.

7. The riveting structure as claimed in claim 1, wherein the volume of the raised portion is slightly greater than the volume of the cover plate riveting hole.
